(19) United States
(12) Patent Application Publication
(10) Pub. No.: US 2025/0228019 A1
(43) Pub. Date: Jul. 10, 2025

(54) Ge-BASED INFRARED DETECTOR AND ELECTRONIC DEVICE INCLUDING THE SAME

(71) Applicant: SAMSUNG ELECTRONICS CO., LTD., Suwon-si (KR)

(72) Inventors: Kyungsang CHO, Suwon-si (KR); Chanwook Baik, Suwon-si (KR); Youngzoon Yoon, Suwon-si (KR)

(73) Assignee: SAMSUNG ELECTRONICS CO., LTD., Suwon-si (KR)

(21) Appl. No.: 18/816,626

(22) Filed: Aug. 27, 2024

(30) Foreign Application Priority Data
Jan. 4, 2024 (KR) 10-2024-0001737

(51) Int. Cl. H01L 31/113; G01J 1/04; G01J 1/44; H01L 31/0232; H01L 31/028

(52) U.S. Cl. CPC H10F 30/282; G01J 1/0407; G01J 1/44; H10F 77/122; H10F 77/413

(57) ABSTRACT

A germanium (Ge)-based infrared detector and an electronic device including the same are provided. The infrared detector according to an embodiment includes a Ge-based infrared absorption layer provided on a substrate; a first electrode layer provided on the infrared absorption layer; a second electrode layer provided on the infrared absorption layer and spaced apart from the first electrode layer in a first direction; and a first gate electrode layer provided between the first electrode layer and the second electrode layer in the first direction, the first gate electrode layer facing the infrared absorption layer and spaced apart from the infrared absorption layer in a second direction crossing the first direction.

### CROSS-REFERENCE TO RELATED APPLICATION

This application is based on and claims priority under 35 U.S.C. § 119 to Korean Patent Application No. 10-2024-0001737, filed on Jan. 4, 2024, in the Korean Intellectual Property Office, the disclosure of which is herein incorporated by reference in its entirety.

### BACKGROUND

### 1. Field

One or more example embodiments of the disclosure relate to a photodetector, and more particularly, to a germanium (Ge)-based infrared detector and an electronic device including the same.

### 2. Description of the Related Art

The intensity of light emitted from a light source (e.g., a laser) of an optical interconnect system may be determined by considering the minimum output and intensity that may be detected by a photodetector of the optical interconnect system.

Photodiodes, which are widely used as photodetectors, have a gain of 1 or less, and thus, there is a limit in their sensitivity in light detection. An avalanche photodiode (APD) or a single photon avalanche diode (SPAD) having a gain of 1 or more has a high driving voltage and a low repetition rate, and therefore, the APD or the SPAD may be difficult for the APD or the SPAD to operate at a high speed above GHz.

Accordingly, the interest is increasing in a phototransistor with a metal-oxide semiconductor field-effect transistor (MOSFET) structure, which has a simpler structure and may have high sensitivity and high gain compared to a bipolar junction transistor (BJT).

### SUMMARY

One or more example embodiments provide a germanium (Ge)-based infrared detector that may have a gain of 1 or more.

Further, one or more example embodiments provide a Ge-based infrared detector with increased light reception sensitivity.

Still further, one or more example embodiments provide a Ge-based infrared detector capable of lowering the operating power of a light-emitting source.

Still further, one or more example embodiments provide an electronic device including such an infrared detector.

Additional aspects will be set forth in part in the description which follows and, in part, will be apparent from the description, or may be learned by practice of the presented embodiments of the disclosure.

According to an aspect of an example embodiment of the disclosure, a germanium (Ge)-based infrared detector is provided on a substrate and includes a Ge-based infrared absorption layer; a first electrode layer provided on the infrared absorption layer; a second electrode layer provided on the infrared absorption layer and spaced apart from the first electrode layer in a first direction; and a first gate electrode layer provided between the first electrode layer and the second electrode layer in the first direction, the first gate electrode layer facing the infrared absorption layer and spaced apart from the infrared absorption layer in a second direction crossing the first direction.

In an example, the infrared absorption layer may extend on or below the first electrode layer and the second electrode layer, and the first electrode layer and the second electrode layer directly contact the infrared absorption layer.

In an example, the infrared absorption layer may extend on or below the first electrode layer and the second electrode layer, wherein the infrared absorption layer may include a first doped layer provided at a position corresponding to the first electrode layer and a second doped layer provided at a position corresponding to the second electrode layer and spaced apart from the first doped layer, and the first electrode layer may be in direct contact with the first doped layer, and the second electrode layer is in direct contact with the second doped layer. Each of the first doped layer and the second doped layer may include one of an n-type dopant and a p-type dopant. In an example, each of the first doped layer and the second doped layer may have a doping concentration gradient in a direction away from the first gate electrode layer.

In an example, the first gate electrode layer may be disposed above or below the infrared absorption layer.

In an example, the infrared detector may further include a second gate electrode layer, the second gate electrode layer facing the first gate electrode layer with the infrared absorption layer therebetween and being spaced apart from the infrared absorption layer.

In an example, the infrared detector may further include a first interlayer material layer between the substrate and the infrared absorption layer, wherein the first interlayer material layer includes a silicon (Si) layer.

In an example, the infrared detector may further include a second interlayer material layer on the substrate, wherein the second interlayer material layer may include a groove, and the infrared absorption layer may be provided in the groove. In an example, the second interlayer material layer may include a third doped layer at a position corresponding to the first electrode layer and a fourth doped layer at a position corresponding to the second electrode layer, wherein the groove may be located between the third doped layer and the fourth doped layer in the first direction, and the first electrode layer may be in direct contact with the third doped layer, and the second electrode layer is in direct contact with the fourth doped layer. In an example, the third and fourth doped layers may be spaced apart from the infrared absorption layer. In an example, the third and fourth doped layers may extend toward a lower surface of the second interlayer material layer. In an example, the third and fourth doped layers may each have a doping concentration gradient in a direction away from the first gate electrode layer. In an example, the third and fourth doped layers may each include one of an n-type dopant and a p-type dopant. In an example, the first gate electrode layer may be disposed above or below the infrared absorption layer. In an example, the infrared detector may further include a second gate electrode layer, the second gate electrode layer facing the first gate electrode layer with the infrared absorption layer therebetween and being spaced apart from the infrared absorption layer.

In an example, the infrared absorption layer may include a plurality of infrared absorption layers, the plurality of infrared absorption layers being stacked in a direction perpendicular to the substrate and spaced apart from each other.

In an example, the substrate may include a base substrate and an interlayer insulating layer on the base substrate.

In an example, the substrate may be a single layer. The substrate may include a silicon layer or a silicon oxide layer, and may be in direct contact with the infrared absorption layer.

According to an aspect of an example embodiment of the disclosure, an electronic device includes an infrared detector. In an example, the electronic device may further include a waveguide connected to the infrared detector, and the infrared detector and the waveguide may be connected to each other by a butt coupling method, an evanescent coupling method, or a diffraction grating coupling method.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 to 12 are cross-sectional views respectively showing first to twelfth germanium-based infrared detectors according to example embodiments;

FIG. 13 is a plan view illustrating an example of a combination of an infrared detector according to an example embodiment and an optical waveguide;

FIGS. 14 to 17 are cross-sectional views showing various examples of cross-section taken along line 14-14′ of FIG. 13;

FIG. 18 is a block diagram schematically showing an optical communication system according to an example embodiment; and

FIG. 19 is a block diagram showing an electronic device according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an optical phased array, an operating method thereof, and an electronic device including the optical phased array according to an embodiment will be described in detail with reference to the accompanying drawings. In the drawings, thicknesses of layers and regions may be exaggerated for clarification of the specification.

The following embodiments described below are merely illustrative, and various modifications may be possible from the embodiments of the disclosure. When an element or layer is referred to as being “on” or “above” another element or layer, the element or layer may be directly on another element or layer or intervening elements or layers. In the descriptions below, like reference numerals in the drawings refer to like elements.

The singular forms are intended to include the plural forms as well, unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise. The operations may not necessarily be performed in the order of sequence.

Also, in the specification, the term “units” or “ . . . modules” denote units or modules that process at least one function or operation, and may be realized by hardware, software, or a combination of hardware and software.

The connections of lines and connection members between constituent elements depicted in the drawings are examples of functional connection and/or physical or circuitry connections, and thus, in practical devices, may be expressed as replaceable or additional functional connections, physical connections, or circuitry connections.

The use of all examples or illustrative terms is simply for explaining the technical idea in detail, and the scope is not limited by the examples or illustrative terms unless limited by the claims.

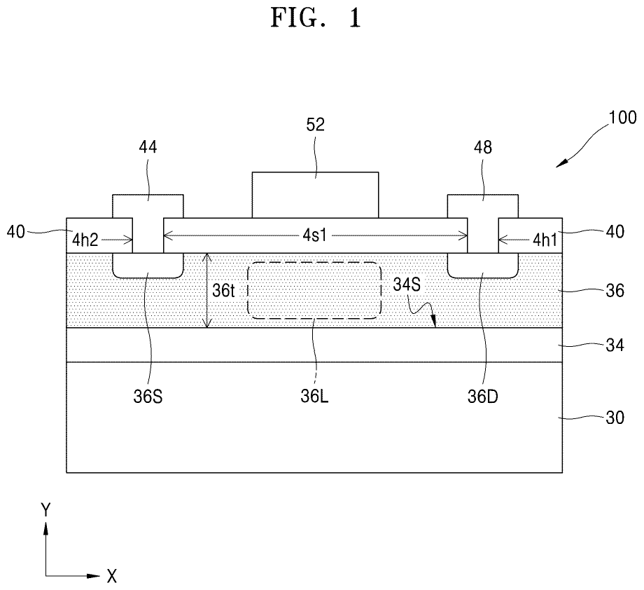

FIG. 1 shows a first infrared detector 100 according to an example embodiment.

Referring to FIG. 1, the first infrared detector 100 may include a first substrate 30 and an interlayer insulating layer 34 that are sequentially stacked. The first substrate 30 may be referred to as a base substrate. The interlayer insulating layer 34 may be provided on one surface of the first substrate 30 and may be provided to cover the entire one surface. In an example, the one surface may be an upper surface of the first substrate 30 but may also be expressed as a lower or side surface depending on a viewpoint from which the first substrate 30 is viewed. In an example, an overall thickness of the interlayer insulating layer 34 may be constant, however, in another example, the overall thickness may not be constant. In an example, the thickness of the interlayer insulating layer 34 may be less than a thickness of the first substrate 30, but is not limited thereto. In an example, the first substrate 30 may be or include a layer including silicon. As an example, the first substrate 30 may be a silicon substrate or may include a silicon substrate but is not limited thereto. In an example, the first substrate 30 includes silicon, and the first substrate 30 may be or include a crystalline silicon substrate, an amorphous silicon substrate, or a polycrystalline silicon substrate. In an example, the interlayer insulating layer 34 may include, but is not limited to, an oxide layer or a nitride layer. In an example, the interlayer insulating layer 34 may be or include an oxide layer including silicon (e.g., SiO₂). In an example, the first substrate 30 and the interlayer insulating layer 34 may be collectively referred to as a substrate. A light absorption layer 36, a first insulating layer 40, and a gate electrode layer 52 may be sequentially stacked on the interlayer insulating layer 34. The light absorption layer 36 may be disposed to face the first substrate 30 with the interlayer insulating layer 34 therebetween. In an example, the light absorption layer 36 may be formed directly on an upper surface 34S of the interlayer insulating layer 34 and may be formed to cover an entire upper surface 34S, but is not limited thereto. In an example, the light absorption layer 36 may be a material layer provided to absorb an infrared ray or a material layer that has a relatively higher absorption rate for an infrared ray than for visible light, or the light absorption layer 36 may include such a material layer. In an example, the light absorption layer 36 may be a material layer including germanium (Ge) or may include a germanium layer, but is not limited thereto. In an example, light absorption layer 36 may include a crystalline, amorphous, or polycrystalline germanium layer. In an example, the light absorption layer 36 may include, but is not limited to, an n-type doped germanium layer (e.g., doped with an n-type impurity). The n-type impurity may include a Group 5 element. In an example, an overall thickness of the light absorbing layer 36 on the interlayer insulating layer 34 may be constant, but in another example, may not be constant.

In an example, a thickness 36t of the light absorption layer 36 may be greater than the thickness of the interlayer insulating layer 34 but is not limited thereto. In an example, the thickness 36t of the light absorption layer 36 may be 3 μm or less, 2.5 μm or less, 2 μm or less, 1.5 μm or less, or 1 μm or less, but is not limited thereto. For example, the thickness 36t of the light absorption layer 36 may be in a range from about 100 nm to about 3 μm, from about 100 nm to about 2.5 μm, or from about 100 nm to about 2 μm, but is not limited thereto. In an example, the light absorption layer 36 may be provided only on a portion of the upper surface 34S of the interlayer insulating layer 34. In an example, the light absorption layer 36 may include a first doped layer 36S and a second doped layer 36D spaced apart from each other. In an example, upper surfaces of the first and second doped layers 36S and 36D may be the same level as an upper surface of the light absorption layer 36. For example, the upper surface of the light absorption layer 36 may include the upper surfaces of the first and second doped layers 36S and 36D, but is not limited thereto. In an example, the first and second doped layers 36S and 36D may be provided at a level below the upper surface of the light absorption layer 36, that is, buried in the light absorption layer 36, and in this case, a first electrode layer 44 and a second electrode layer 48 may extend into the light absorption layer 36 through the upper surface of the light absorption layer 36 and may contact the first and second doped layers 36S and 36D. In an example, the first and second doped layers 36S and 36D may be regions of the light absorption layer 36 doped with a conductive impurity. For example, the first and second doped layers 36S and 36D may be an n-type doped layer doped with an n-type conductive impurity or a p-type doped layer doped with a p-type conductive impurity.

In an example, the first doped layer 36S may be a layer doped to have a doping concentration gradient, for example, the first doped layer 36S may be a layer doped with a conductive impurity in a manner in which the doping concentration increases in a first direction. In an example, the first direction is a horizontal direction (e.g., an X-axis direction), and the first direction may be a direction away from the gate electrode layer 52 or a direction closer to the gate electrode layer 52. In an example, the first doping layer 36S may have a doping concentration gradient in a second direction perpendicular to the first direction (e.g., a perpendicular direction) instead of the first direction. The second doped layer 36D may have the same doping concentration or the same doping concentration gradient as the first doped layer 36S, but is not limited thereto. For example, the first and second doped layers 36S and 36D may have different doping concentration gradients or different doping concentrations.

When the first and second doped layers 36S and 36D are n-type doped layers, the first and second doped layers 36S and 36D may be at least one type of n+ type and n++ type doped layers. For example, the first and second doped layers 36S and 36D may be n++ doped layers. For example, the first doped layer 36S may be a layer doped in a form of n+n++ type in a direction away from the gate electrode layer 52 or in the opposite direction, and the second doped layer 36D may be a layer doped in be a layer doped in the form of n+n++ type in a direction away from the gate electrode layer 52 or in the opposite direction.

In an example, even in a case in which the first and second doped layers 36S and 36D are p-type doped layers doped with p-type conductive impurities, the doping concentration or doping structure of each doped layer 36S and 36D may be the same as described above with respect to a case in which the first and second doped layers 36S and 36D are n-type doped layers, but are not limited thereto.

In an example, the first and second doped layers 36S and 36D may be expressed as first and second doped regions. In an example, one of the first and second doped layers 36S and 36D may be a source region, and the other may be a drain region. In an example, the n-type conductive impurity may include phosphorus (P), antimony (Sb), gallium (Ga), beryllium (Be), and zinc (Zn), but is not limited thereto. In an example, the p-type conductive impurity may include boron (B) but is not limited thereto.

The first insulating layer 40 may be provided on the light absorption layer 36. The first insulating layer 40 may include a first via hole 4h1 and a second via hole 4h2 spaced apart from each other. The first and second via holes 4h1 and 4h2 may be expressed as through holes in that the first and second via holes 4h1 and 4h2 are formed through the first insulating layer 40. The first and second via holes 4h1 and 4h2 may be separated from each other by a first distance 4s1. The first distance 4s1 may be expressed as a first width, or as a channel length or channel width. In an example, the first distance 4s1 may be 1 μm or less, for example, in a range from about 0.1 μm to about 0.5 μm, but is not limited thereto. Accordingly, an operating voltage of the first infrared detector 100 may be reduced to 3V or less.

In an example, the first insulating layer 40 may cover an entire upper surface of the light absorption layer 36 except for a portion exposed through the first and second via holes 4h1 and 4h2 but is not limited thereto. In an example, the first insulating layer 40 may include an oxide layer or a nitride layer. As an example, the first insulating layer 40 may include a silicon oxide layer but is not limited thereto. In an example, a thickness of the first insulating layer 40 may be less than the thickness of the light absorption layer 36 but is not limited thereto. The first via hole 4h1 may be located on the first doped layer 36S, and the second via hole 4h2 may be located on the second doped layer 36D. Accordingly, the first doped layer 36S may be exposed through the first via hole 4h1, and the second doped layer 36D may be exposed through the second via hole 4h2. A width of the first via hole 4h1 may be less than a width of the first doped layer 36S, and a width of the second via hole 4h2 may be less than a width of the second doped layer 36D but are not limited thereto. In an example, the first electrode layer 44 filling the first via hole 4h1 and the second electrode layer 48 filling the second via hole 4h2 may be provided on the first insulating layer 40. The first electrode layer 44 may completely fill the first via hole 36S and may extend onto a portion of the first insulating layer 40 around the first via hole 36S. In an example, the first electrode layer 44 may be a single layer formed of the same material. In an example, the first electrode layer 44 may include a vertical portion (e.g., a vertical layer) that fills the first via hole 4h1 and a horizontal portion (e.g., a horizontal layer) that covers an upper surface of the vertical portion. A material of the vertical portion and a material of the horizontal portion may be the same or different from each other. The second electrode layer 48 may completely fill the second via hole 4h2 and may extend onto a portion of the first insulating layer 40 around the second via hole 4h2. In an example, the second electrode layer 48 may also be a single layer like the first electrode layer 44 and/or may include a vertical portion (e.g., a vertical layer) and a horizontal portion (e.g., a horizontal layer). In an example, when the first doped layer 36S is a source region, the first electrode layer 44 may be expressed as a source electrode or a source electrode layer. When the second doped layer 36D is a drain region, the second electrode layer 48 may be expressed as a drain electrode or a drain electrode layer.

The gate electrode layer 52 may be provided on the first insulating layer 40 between the first electrode layer 44 and the second electrode layer 48. The first insulating layer 40 may be a gate insulating layer. In an example, the gate electrode layer 52 may be located in the middle between the first electrode layer 44 and the second electrode layer 48. A distance (or a space) between the gate electrode layer 52 and the first electrode layer 44 may be the same or substantially the same with a distance (or a space) between the gate electrode layer 52 and the second electrode layer 48, but in another example, may not be the same. For example, the distance between the gate electrode layer 52 and the first electrode layer 44 and the distance between the gate electrode layer 52 and the second electrode layer 48 may be different from each other. When light (e.g., infrared ray) is incident on the light absorption layer 36 that performs as a channel layer, a photocurrent may be generated by a photoelectric effect. The gate electrode layer 52 may be a control electrode layer provided to control a flow of a photocurrent. In an example, the gate electrode layer 52 may be represented as a third electrode.

Reference numeral 36L indicates a region on which light is incident in a side direction or lateral direction of the light absorption layer 36. In an example, a width of the region 36L into which light is incident in a horizontal direction (e.g., an X-axis direction) may be the same as a width of the gate electrode layer 52 or may be less or greater than the width of the gate electrode layer 52. The first infrared detector 100 may be a transistor-type photodetector that controls the flow of photocurrent generated in the light absorption layer 36, which may be a channel layer, to the gate electrode layer 52. That is, the first infrared detector 100 may be a photo transistor for infrared detection. Because the gate electrode layer 52 is provided on the light absorption layer 36, the first infrared detector 100 may be a top gate photo transistor.

In an example, in the first infrared detector 100, a channel layer gap, that may correspond to a thickness of the light absorption layer 36, may be reduced to 1 μm or less. In this way, an operation of the first infrared detector 100 at a high speed at a GHz level is possible. For example, the first infrared detector 100 may be capable of performing a high-speed operation at 5 GHz or higher or 10 GHz or higher. These characteristics may also be applied to other infrared detectors according to one or more example embodiments described below.

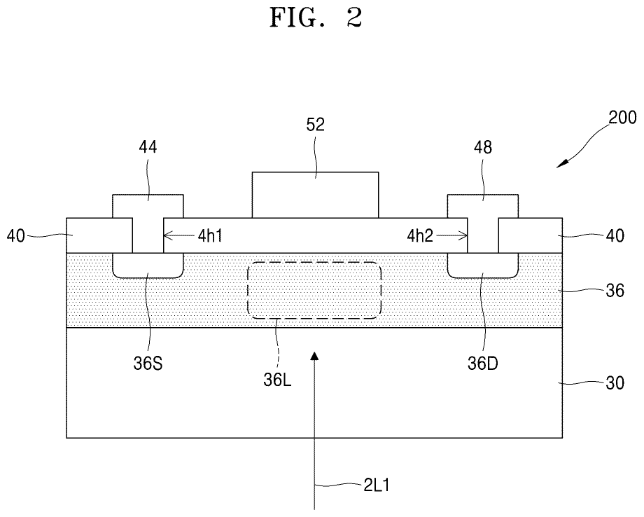

FIG. 2 shows a second infrared detector 200 according to an example embodiment. Only parts that are different from the first infrared detector 100 of FIG. 1 will be described.

Referring to FIG. 2, the second infrared detector 200 may be the same as the first infrared detector 100 except that the interlayer insulating layer 34 is removed. Accordingly, in the second infrared detector 200, the first substrate 30 and the light absorption layer 36 may be in direct contact with each other.

Accordingly, in the second infrared detector 200, the first substrate 30 may have a relatively low absorption rate for an infrared ray, for example, the first substrate 30 may be a silicon substrate. In this case, an infrared ray 2L1 may be incident on the first substrate 30 from below the first substrate 30 and may reach the light absorption layer 36 passing through the first substrate 30. In an example, in the case of the second infrared detector 200, infrared ray 2L1 may be incident from below the first substrate 30 through a lower surface of the first substrate 30, but an infrared ray may also be incident in a lateral direction of the light absorption layer 36. That is, in the case of the second infrared detector 200, infrared rays may reach the light absorption layer 36 in two ways. The above two ways may be directly related to a coupling method between the second infrared detector 200 and a waveguide. In an example, the second infrared detector 200 and the waveguide may be coupled using an evanescent coupling method or a butt coupling method.

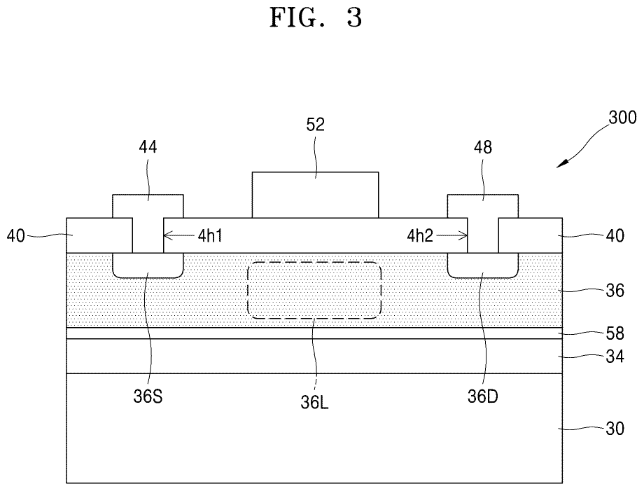

FIG. 3 shows a third infrared detector 300 according to an example embodiment. Only parts that are different from the first infrared detector 100 of FIG. 1 will be described.

Referring to FIG. 3, the third infrared detector 300 includes a first interlayer material layer 58 provided between the interlayer insulating layer 34 and the light absorption layer 36. The remaining configuration may be the same as that of the first infrared detector 100.

In an example, the first interlayer material layer 58 may be a material layer that does not absorb an infrared ray or has a relatively low infrared absorption rate compared to the light absorption layer 36. As an example, the first interlayer material layer 58 may include a material layer that has characteristics that may be used as a base layer for growth of the light absorption layer 36. In one example, the first interlayer material layer 58 may include a material layer that has the above characteristics and has a crystal lattice structure similar to that of the light absorption layer 36. For example, the light absorption layer 36 may be a Ge layer, and the first interlayer material layer 58 may be a layer including silicon (Si) or a silicon layer but is not limited thereto. In an example, a thickness of the first interlayer material layer 58 may be less than the thickness of the interlayer insulating layer 34 but is not limited thereto.

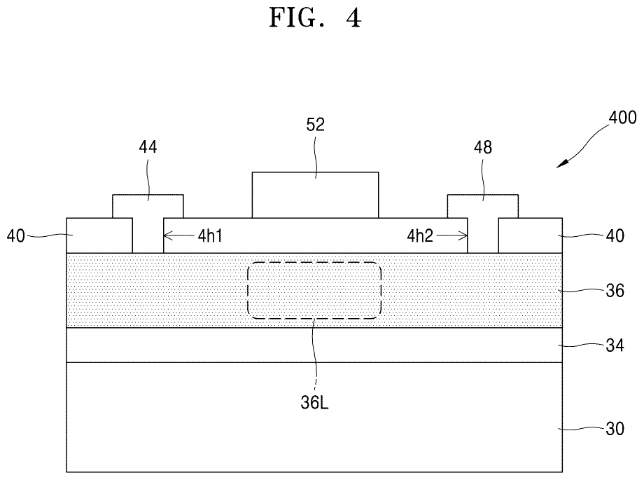

FIG. 4 shows a fourth infrared detector 400 according to an example embodiment. Only parts that are different from the first infrared detector 100 of FIG. 1 will be described.

Referring to FIG. 4, in the fourth infrared detector 400, there is no separate doped layer between the light absorption layer 36 and the first and second electrode layers 44 and 48. Accordingly, the first electrode layer 44 and the second electrode layer 48 may be in direct contact with the light absorption layer 36. As a result, the fourth infrared detector 400 may be the same as when the first and second doped layers 36S and 36D are removed from the first infrared detector 100. In an example, a material of the first and second electrode layers 44 and 48 of the fourth infrared detector 400 may be the same as a material of the first and second electrode layers 44 and 48 of the first infrared detector 100, but in another example, may be different from the material of the first and second electrode layers 44 and 48 of the first infrared detector 100.

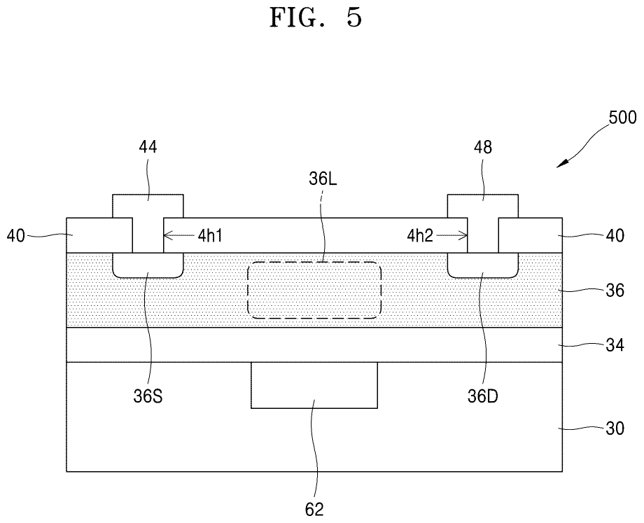

FIG. 5 shows a fifth infrared detector 500 according to an example embodiment. Only parts that are different from the first infrared detector 100 of FIG. 1 will be described.

Referring to FIG. 5, in a case of the fifth infrared detector 500, a gate electrode layer 62 may be located below the light absorption layer 36, which is a channel layer. The gate electrode layer 62 may be formed on an underside (or on a lower surface) of the interlayer insulating layer 34 and may be covered with the first substrate 30. In this stacked structure, the interlayer insulating layer 34 may function as a gate insulating layer. The gate electrode layer 62 may be provided below or corresponding to the light incident region 36L of the light absorption layer 36. Unlike the first to fourth infrared detectors 100, 200, 300, and 400 that have a top gate structure, the fifth infrared detector 500 may be a photo transistor with a bottom gate structure.

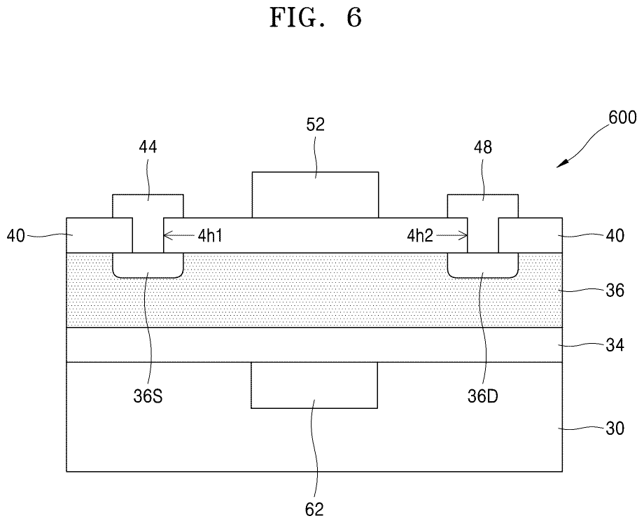

FIG. 6 shows a sixth infrared detector 600 according to an example embodiment. Only parts that are different from the first infrared detector 100 of FIG. 1 will be described.

Referring to FIG. 6, the sixth infrared detector 600 may be a photo transistor with a double gate structure, and may have the gate electrode layer 52 above the light absorption layer 36, and the gate electrode layer 62 below the light absorption layer 36. In the sixth infrared detector 600, the gate electrode layer 52 provided above the light absorption layer 36 may be referred to as an upper gate electrode layer or a top gate electrode layer, and the gate electrode layer 62 provided below the light absorption layer 36 may be referred to as a lower gate electrode layer or a bottom gate electrode layer. The sixth infrared detector 600 may correspond to a combination of the first infrared detector 100 of FIG. 1 and the fifth infrared detector 500 of FIG. 5.

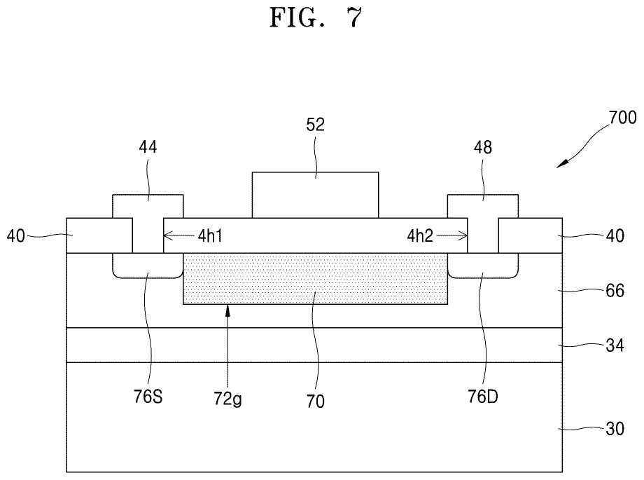

FIG. 7 shows a seventh infrared detector 700 according to an example embodiment. Only parts that are different from the first infrared detector 100 of FIG. 1 will be described.

Referring to FIG. 7, in the seventh infrared detector 700, a second interlayer material layer 66, a light absorption layer 70, the first insulating layer 40, and the gate electrode layer 52 may be stacked sequentially on the interlayer insulating layer 34. In an example, a material of the second interlayer material layer 66 may be the same as a material of the first interlayer material layer 58 of FIG. 3 but is not limited thereto. In an example, the second interlayer material layer 66 may be a material layer doped with an n-type or p-type conductive impurity (or dopant). The second interlayer material layer 66 may include a third doped layer 76S and a fourth doped layer 76D spaced apart from each other. In an example, a doping concentration of the third and fourth doped layers 76S and 76D may be greater than a doping concentration of the second interlayer material layer 66 around the third and fourth doped layers 76S and 76D. A type of a dopant used to form the third and fourth doped layers 76S and 76D may be opposite to a type of a dopant injected into the second interlayer material layer 66. For example, the third and fourth doped layers 76S and 76D may include an n-type dopant, and the second interlayer material layer 66 may include a p-type dopant. In an example, the third doped layer 76S may correspond to the first doped layer 36S of the first infrared detector 100, and the fourth doped layer 76D may correspond to the second doped layer 36D of the first infrared detector 100. Upper surfaces of the third and fourth doped layers 76S and 76D may be parts of an upper surface of the second interlayer material layer 66, and thus, the upper surfaces of the third and fourth doped layers 76S and 76D and the upper surface of the second interlayer material layer 66 may be on the same plane. The second interlayer material layer 66 may include a groove 72g formed between the third doped layer 76S and the fourth doped layer 76D. In an example, a depth of the groove 72g may be deeper than a depth of the third and fourth doped layers 76S and 76D but is not limited thereto. The groove 72g may be in contact with the third and fourth doped layers 76S and 76D. In one example, the groove 72g may be filled with the light absorption layer 70. As an example, the groove 72g may be completely filled with the light absorption layer 70. A material and/or a thickness of the light absorption layer 70 may be the same as that of the light absorption layer 36 of the first infrared detector 100 but is not limited thereto. The depth of the groove 72g may be determined by considering the thickness of the light absorption layer 70, and the thickness of the second interlayer material layer 66 may be determined by considering these points. In an example, the groove 72g may be formed after the third and fourth doped layers 76S and 76D are formed, but in another example, may be formed before the third and fourth doped layers 76S and 76D are formed. For example, the groove 72g may be formed at a predetermined position in the second interlayer material layer 66, the groove 72g may be filled with the light absorption layer 70, and then the third and fourth doped layers 76S and 76D may be formed. The first insulating layer 40 may be formed on the second interlayer material layer 66, may be formed to cover an entire upper surface of the light absorbing layer 70, and may be directly connected to an entire upper surface of the light absorbing layer 70.

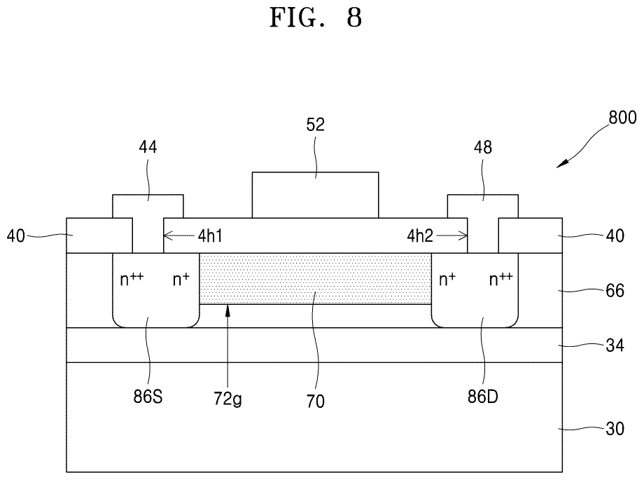

FIG. 8 shows an eighth infrared detector 800 according to an example embodiment. Only parts that are different from the seventh infrared detector 700 of FIG. 7 will be described.

Referring to FIG. 8, the eighth infrared detector 800 may include a fifth doped layer 86S and a sixth doped layer 86D provided in the second interlayer material layer 66. A location of the fifth doped layer 86S may correspond to the third doped layer 76S, and a location of the sixth doped layer 86D may correspond to the fourth doped layer 76D. A thickness or a depth of the fifth and sixth doped layers 86S and 86D may be the same as the thickness or the depth of the second interlayer material layer 66. Accordingly, the fifth and sixth doped layers 86S and 86D may contact the interlayer insulating layer 34, an entire left side surface of the light absorption layer 70 may be in contact with the fifth doped layer 86S, and an entire right side surface may be in contact with the sixth doped layer 86D. In an example, a doping concentration and/or a doping type of the fifth doped layer 86S may correspond to that of the first doped layer 36S of the first infrared detector 100, and a doping concentration and/or a doping type of the sixth doped layer 86D may correspond to that of the second doped layer 36D of the first infrared detector 100. For example, the fifth and sixth doped layers 86S and 86D may both have an n+n++ doping type. For example, in the fifth and sixth doped layers 86S and 86D, a region close to the light absorption layer 70 may be a region doped with n+, and a region relatively far from the light absorption layer 70 may be a region doped with n++. In other words, the fifth and sixth doped layers 86S and 86D may have a doping concentration gradient in which the doping concentration increases in a direction away from the light absorption layer 70.

The eighth infrared detector 800 may be viewed as a modified seventh infrared detector 700 in which the third and fourth doped layers 76S and 76D extend toward a bottom of the second interlayer material layer 66 in the seventh infrared detector 700.

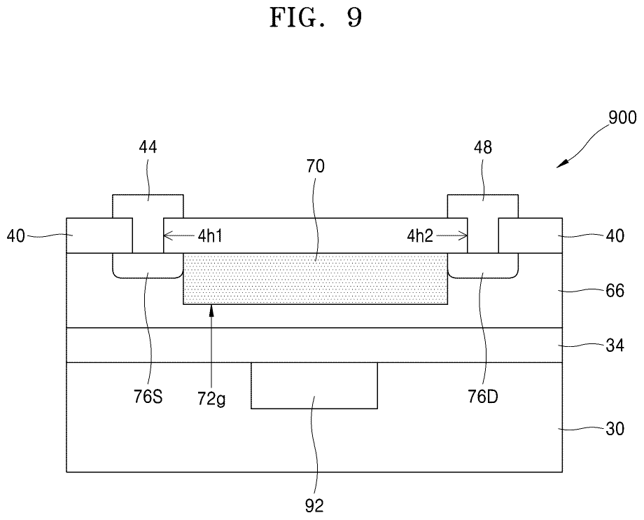

FIG. 9 shows a ninth infrared detector 900 according to an example embodiment. Only parts that are different from the seventh infrared detector 700 of FIG. 7 will be described.

Referring to FIG. 9, a gate electrode layer 92 may be provided below the light absorption layer 70, which is a channel layer, and there is no gate electrode layer above the light absorption layer 70. A location and a material of the gate electrode layer 92 may be the same as those of the gate electrode layer 62 provided as the bottom gate of the fifth infrared detector 500 of FIG. 5 but is not limited thereto.

As a result, the ninth infrared detector 900 may be the same as a case in which the gate electrode layer 52 is disposed on the bottom of the interlayer insulating layer 34 below the light absorption layer 70 in the seventh infrared detector 700 of FIG. 7. In other words, the ninth infrared detector 900 may correspond to a case in which the seventh infrared detector 700, which is a photo transistor with a top gate structure, is modified into a photo transistor with a bottom gate structure.

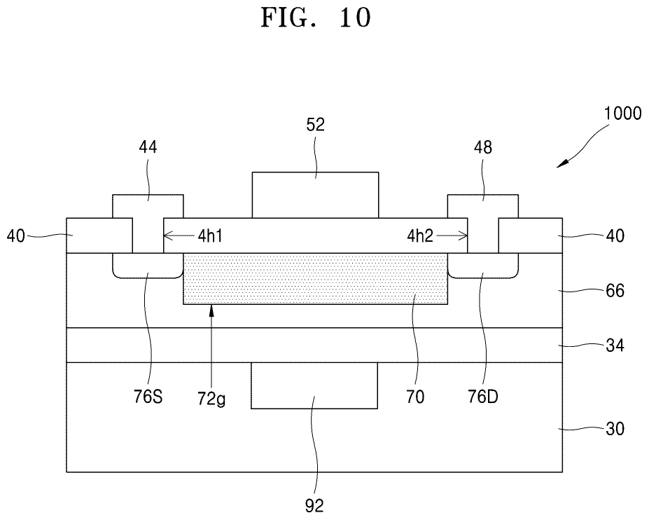

FIG. 10 shows a tenth infrared detector 1000 according to an example embodiment.

The tenth infrared detector 1000 may correspond to a case in which the gate electrode layer 52 is further provided on the first insulating layer 40 between the first and second electrode layers 44 and 48 above the light absorption layer 70 in the ninth infrared detector 900 of FIG. 9. As a result, the tenth infrared detector 1000 may be a double gate photo transistor including both a top gate and a bottom gate.

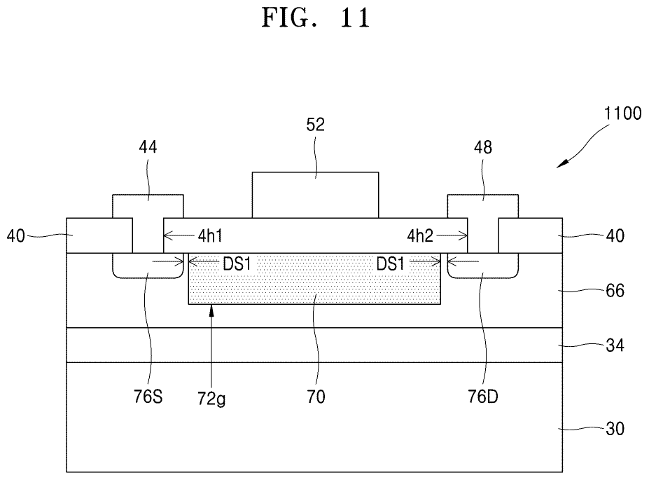

FIG. 11 shows an eleventh infrared detector 1100 according to an example embodiment. Only parts that are different from the seventh infrared detector 700 of FIG. 7 will be described.

Referring to FIG. 11, in the eleventh infrared detector 1100, the third and fourth doped layers 76S and 76D and the light absorption layer 70 may not directly contact each other. In an example, the light absorption layer 70 and the third and fourth doped layers 76S and 76D may be spaced apart from each other by a first distance DS1. The first distance DS1 may be a distance in which at least a portion of photoelectrons generated in the light absorption layer 70 may be transferred to the third and fourth doped layers 76S and 76D. Because crystal lattice structures of the second interlayer material layer 66 and the light absorption layer 70 may be the same or similar to each other, it may be a problem if the first distance DS1 is large enough to completely block light current transmission. The light absorption layer 70 and the third and fourth doped layers 76S and 76D may be separated by the first distance DS1, which may allow the eleventh infrared detector 1100 to maintain at least a minimum sensitivity. Therefore, the first distance DS1 may be set to a distance at which the minimum sensitivity or lowest sensitivity in the effective sensitivity range of the eleventh infrared detector 1100 is secured, through simulation or experiment.

The example in which the light absorption layer 70 and the third and fourth doped layers 76S and 76D of the eleventh infrared detector 1100 are spaced apart by the first distance DS1 may be applied to at least some of the infrared detectors illustrated above, for example, the seventh to tenth infrared detectors 700, 800, 900, and 1000.

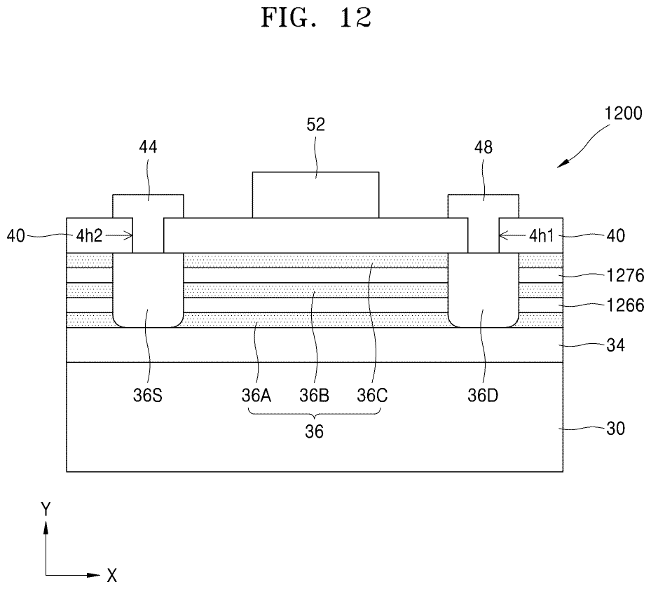

FIG. 12 shows a twelfth infrared detector 1200 according to an example embodiment. Only parts that are different from the first infrared detector 100 of FIG. 1 will be described.

Referring to FIG. 12, in the twelfth infrared detector 1200, the light absorption layer 36 may include a first sub-light absorption layer 36A, a second sub-light absorption layer 36B, and a third sub-light absorption layer 36C, which are sequentially stacked in a vertical direction (e.g., a Y-axis direction) and spaced apart from each other. In an example, thicknesses of the first to third sub-light absorption layers 36A, 36B, and 36C may be the same, but in another example, may be different. In an example, the thickness of each of the first to third sub-light absorption layers 36A, 36B, and 36C may be constant or substantially constant, but is not limited thereto. In an example, a material of the first to third sub-light absorption layers 36A, 36B, and 36C may be the same as a material of the light absorption layer 36 of the first infrared detector 100, but may not be the same. For example, all of the first to third sub-light absorption layers 36A, 36B, and 36C may include an infrared absorbing material, but some or all of the materials of the first to third sub-light absorption layers 36A, 36B, and 36C may include an infrared absorbing material other than Ge.

In an example, a first sub-interlayer material layer 1266 and a second sub-interlayer material layer 1276 may be provided between the first to third sub-light absorption layers 36A, 36B, and 36C such that the first to third sub-light absorption layers 36A, 36B, and 36C do not contact each other. The first sub-interlayer material layer 1266 may be provided between the first and second sub-light absorption layers 36A and 36B, and the second sub-interlayer material layer 1276 may be provided between the second sub-light absorption layer 36B and the third sub-light absorption layer 36C. A material of the first and second sub-interlayer material layers 1266 and 1276 may be the same as the material of the first interlayer material layer 58 of the third infrared detector 300 of FIG. 3 but is not limited thereto. In an example, the light absorption layer 36 may include more than three sub-light absorption layers or two sub-light absorption layers, and in this case, a sub interlayer material layer may be provided between the sub-light absorption layers.

In the case of the twelfth infrared detector 1200, the first doped layer 36S may extend downward toward the interlayer insulating layer 34 passing through all of the first to third sub-light absorption layers 36A, 36B, and 36C and the first and second sub-interlayer material layers 1266 and 1276. That is, the first doped layer 36S may be in contact with the interlayer insulating layer 34. Like the first doped layer 36S, the second doped layer 36D may also extend downward and contact the interlayer insulating layer 34.

The example in which the channel layer of the twelfth infrared detector 1200 is a multilayer channel including a plurality of sub light absorption layers 36A, 36B, and 36C, the plurality of interlayer material layers 1266 and 1276 are provided between each channel, and the doped layer is modified to extend downward as described above may also be applied to any one of the infrared detectors illustrated in FIGS. 2 to 11. In the case of the fourth infrared detector 400 illustrated in FIG. 4, the light absorption layer 36 may be the multilayer channel, and the first and second electrode layers 44 and 48 may be formed to extend toward the interlayer insulating layer 34 passing through the multilayer channel.

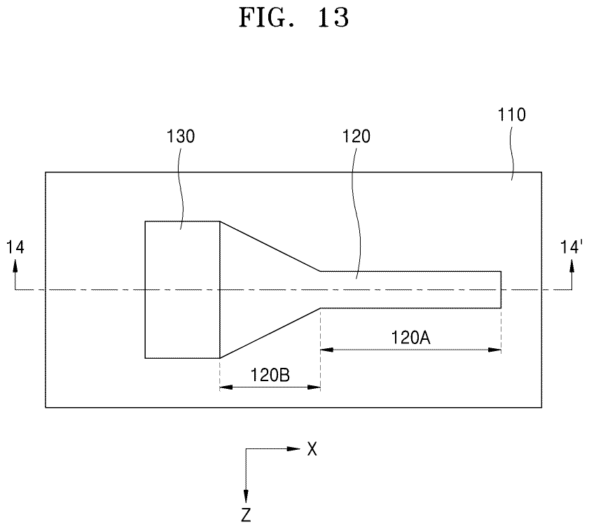

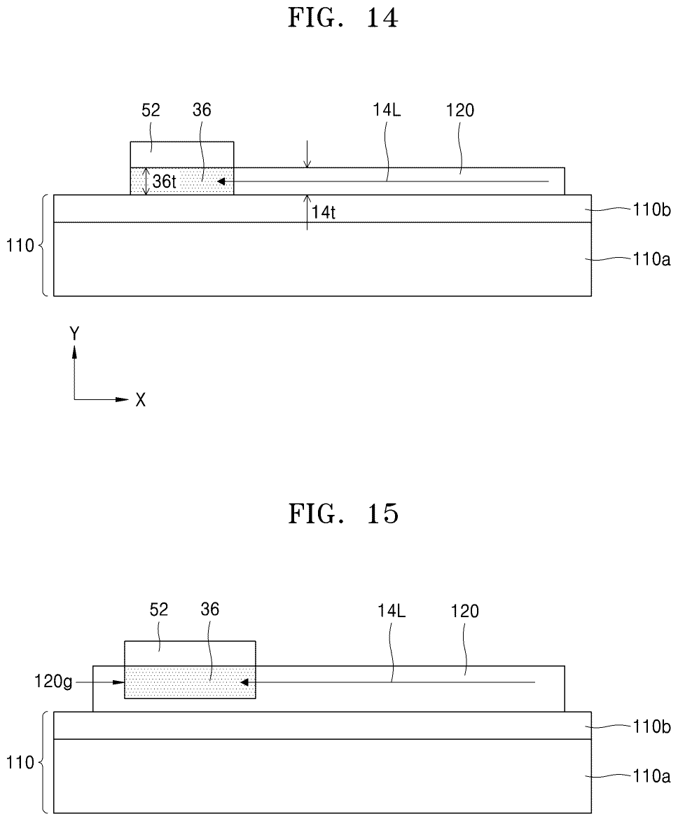

FIG. 13 is a plan view illustrating an example of a structure (or a combined result) in which an infrared detector according to an embodiment and an optical waveguide are combined, and FIGS. 14 to 17 are various example cross-sectional views taken along line 14-14′ of FIG. 13. In FIGS. 14 to 17, for brevity of description, only some components (e.g., gate electrode layer 52, light absorption layer 36) of the infrared detector 130 are shown, but the infrared detector 130 may include one or more additional elements of the first to the twelfth infrared detectors described above as described above.

Referring to FIG. 13 and FIGS. 14 to 17 together, an optical waveguide 120 and an infrared detector 130 may be provided on a second substrate 110. Although not shown in the drawing, the optical waveguide 120 and the infrared detector 130 may be covered with a material having a lower refractive index than a material of the optical waveguide 120. For example, at least a side surface and an upper surface of the optical waveguide 120 that do not face or contact the infrared detector 130 may be covered with a material layer having a lower refractive index than that of the optical waveguide 120. In this way, light (e.g., infrared ray) transmitted through the optical waveguide 120 may be prevented from leaking through the side and upper surfaces of the optical waveguide 120 that do not face or contact the infrared detector 130. In one example, the optical waveguide 120 may include a waveguide that has relatively high infrared transmission efficiency compared to visible light. In other words, the optical waveguide 120 may include a waveguide that has a relatively low loss rate of infrared light compared to visible light during a light transmission process. In one example, the optical waveguide 120 may include a silicon waveguide including silicon or a waveguide including silicon. The optical waveguide 120 may also be referred to as a wave path. The second substrate 110 may be provided in consideration of the light transmission characteristics described above of the optical waveguide 120. In one example, the second substrate 110 may include a substrate including a material having a lower refractive index than the optical waveguide 120 or may be a substrate including such a material. As an example, the second substrate 110 may include a silicon oxide (e.g., SiO₂) layer or a sapphire substrate, but is not limited thereto. In one example, the second substrate 110 may be a single layer or a multilayer, and in the case of a multilayer, an uppermost layer of the second substrate 110 may be a layer with a lower refractive index than the optical waveguide 120.

As shown in FIG. 13, the optical waveguide 120 may have a structure having a length in the horizontal direction (e.g., the X-axis direction) on the second substrate 110, and a width of the waveguide 120 may vary in the vertical direction (e.g., a Z-axis direction) while moving in the horizontal direction but is not limited thereto. For example, the optical waveguide 120 may be entirely a continuum, and therefore, the optical waveguide 120 does not have a physically disconnected or connection boundary between both ends in a longitudinal direction (e.g., the X-axis direction). In one example, the optical waveguide 120 may include a first section 120A, a width of which is constant, and a second section 120B, a width of which varies, but is not limited to this example. The first and second sections 120A and 120B may be continuous. That is, the second section 120B begins immediately following the first section 120A. A width of the first section 120A may be less than a width of the second section 120B. The second section 120B may be located between the first section 120A and the infrared detector 130. The width of the second section 120B may gradually increase from the first section 120A to the infrared detector 130. As a result, the widths of both ends of the second section 120B may be different from each other, and the width may increase or decrease from one end to the other of the second section 120B. The width of the second section 120B may be narrowest at a position at which the second section 120B meets the first section 120A or at a boundary with the first section 120A, and may be widest at a position facing or adjacent to the infrared detector 130 or in contact with the infrared detector 130. In one example, the width of the waveguide 120 may be constant over the entire length, that is, the width of the second section 120B may be constant as the width of the first section 120A and does not change according to a length of the second section 120B. In this example, the width of the second section 120B that is in contact with the infrared detector 130 may be less than a width of the infrared detector 130. In one example, a portion of the waveguide 120 that contacts the infrared detector 130 may have a width (e.g., the distance 4s1 between the first and second via holes 4h1 and 4h2) corresponding to the width of the light absorption layer 36 of the infrared detector 130 but is not limited thereto. In one example, the infrared detector 130 may be one of the infrared detectors 100, 200, 300, 400, 500, 600, 700, 800, 900, 1000, 1100, and 1200 described above. The infrared detector 130 may be in contact with the second portion 120B of the waveguide 120 but is not limited thereto. For example, a light transmission element that minimizes transmission loss of light transmitted through the optical waveguide 120 may be provided between the second section 120B of the optical waveguide 120 and the infrared detector 130.

Referring to FIGS. 13 and 14 together, the second substrate 110 may have a layer structure in which a lower layer 110a and an upper layer 110b are sequentially stacked. In one example, the lower layer 110a may include a semiconductor layer (e.g., a silicon layer), but is not limited thereto. In one example, the upper layer 110b may include a material layer having a lower refractive index than the optical waveguide 120 and may include oxide or nitride. As an example, the upper layer 110b may include, but is not limited to, a silicon oxide layer. The optical waveguide 120 and the light absorption layer 36 may be formed in different regions on the upper layer 110b. In one example, the light absorption layer 36 and the optical waveguide 120 may be in contact with each other, and light 14L transmitted through the optical waveguide 120 may be transmitted toward the light absorption layer 36. In one example, the light 14L may be transmitted while being totally internally reflected within the optical waveguide 120. In one example, the light 14L may be light belonging to an infrared band and, for example, may include short-wavelength infrared light. In one example, the thickness 36t of the light absorption layer 36 and a thickness 12t of the optical waveguide 120 may be substantially the same, or may be different from each other. The light absorption layer 36 may be in contact with a surface of the optical waveguide 120 from which light is emitted. The gate electrode layer 52 may be provided on the light absorption layer 36.

In one example, the layer structure, in which the second substrate 110, the light absorption layer 36, and the gate electrode layer 52 are sequentially stacked, may function as the infrared detector described above (e.g., the first infrared detector 100).

Referring to FIGS. 13 and 15 together, the optical waveguide 120 may be formed on the upper layer 110b of the second substrate 110, and a groove 120g may be formed in the optical waveguide 120. The groove 120g included in the optical waveguide 120 may be filled with the light absorption layer 36. Because the groove 120g is a space to be filled with the light absorption layer 36, the groove 120g may be formed considering a thickness or a width of the light absorption layer 36. An upper surface of the light absorption layer 36 that completely fills the groove 120g may be flat. The upper surface of the light absorption layer 36 may have the same height as an upper surface of the optical waveguide 120 around the groove 120g. The upper surface of the light absorption layer 36 and the waveguide 120 may form the same plane but is not limited thereto.

A layer structure including the second substrate 110, the light absorption layer 36, and the gate electrode layer 52 sequentially stacked in FIG. 15 may function as an infrared detector.

In an optical interconnection mechanism, in which a waveguide and an infrared detector are combined, examples of which are illustrated in FIGS. 14 and 15, light 14L transmitted through the optical waveguide 120 may be directly transmitted toward a side surface of the light absorption layer 36. Therefore, in the optical interconnection mechanism illustrated in FIGS. 14 and 15, the optical waveguide 120 and the infrared detector may be viewed as coupled by butt coupling.

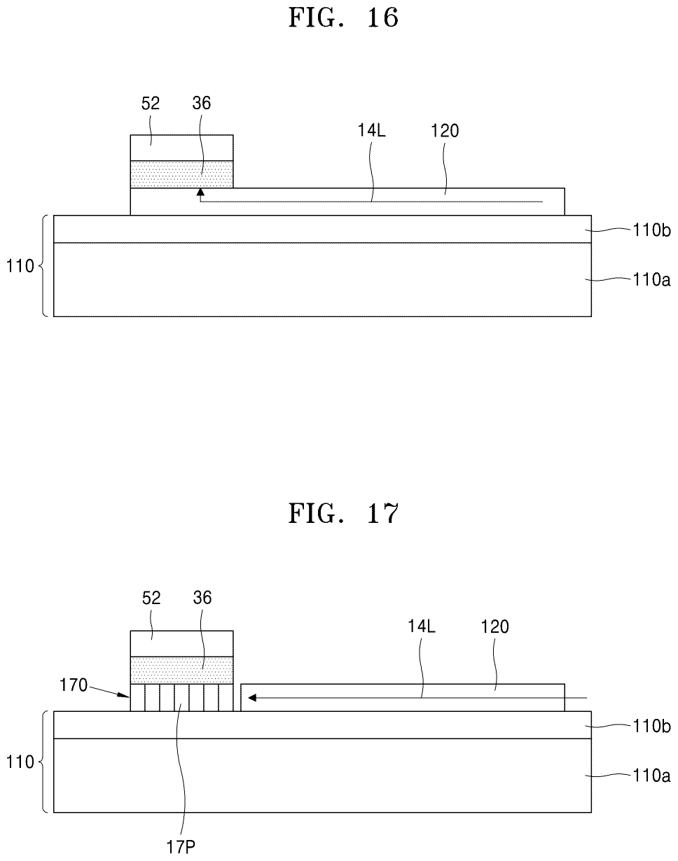

Referring to FIGS. 13 and 16 together, the optical waveguide 120 may be formed on the upper layer 110b of the second substrate 110, and the light absorption layer 36 and the gate electrode layers 52 may be sequentially stacked on a portion of the upper surface of the waveguide 120. The light absorption layer 36 may be provided on the upper surface of one end of the waveguide 120. That is, a lower surface of the light absorption layer 36 may be in contact with the upper surface of the waveguide 120. Accordingly, the light 14L1 transmitted toward the light absorption layer 36 through the optical waveguide 120 may be transmitted toward the light absorption layer 36 through a lower surface of the light absorption layer 36 in an evanescent mode. The layer structure including the second substrate 110, the optical waveguide 120, the light absorption layer 36, and the gate electrode layer 52 sequentially stacked in FIG. 16 may function as an infrared detector. Therefore, the optical interconnection mechanism illustrated in FIG. 16 may be viewed as a combination of an infrared detector and the optical waveguide 120 using an evanescent coupling method.

Referring to FIGS. 13 and 17 together, the optical waveguide 120 and a diffraction grating 170 may be provided in the horizontal direction on the upper layer 110b of the second substrate 110. The diffraction grating 170 and the optical waveguide 120 may be arranged adjacent to each other. In one example, the diffraction grating 170 may include a plurality of diffraction patterns 17P arranged in parallel with each other. The plurality of diffraction patterns 17P may be aligned to be spaced apart from each other in the longitudinal direction of the optical waveguide 120. Each diffraction pattern 17P may be a line-shaped pattern with a length in a direction perpendicular to the longitudinal direction of the waveguide 120 but is not limited thereto. The light absorption layer 36 may be provided on the diffraction grating 170, and the gate electrode layer 52 may be provided on the light absorption layer 36. The diffraction grating 170 may be disposed adjacent to a light emission surface of the optical waveguide 120. Accordingly, the light 14L transmitted through the optical waveguide 120 may be emitted toward the diffraction grating 170. The plurality of diffraction patterns 17P of the diffraction grating 170 may be provided such that light incident from the optical waveguide 120 is diffracted toward the light absorption layer 36.

Accordingly, the light incident on the diffraction grating 170 from the optical waveguide 120 may be diffracted and incident on the lower surface of the light absorption layer 36. The light absorption layer 36 and the gate electrode layer 52 sequentially stacked on the diffraction grating 170 may be regarded as an infrared detector according to one or more example embodiments described above. Therefore, the diffraction grating 170 may be viewed as an optical element that optically connects the optical waveguide 120 and the infrared detector.

As a result, FIG. 17 illustrates an optical interconnection mechanism in which the infrared detector and the optical waveguide 120 are coupled by a diffraction grating coupling method.

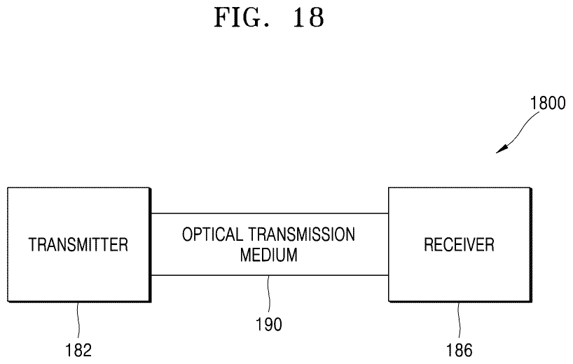

FIG. 18 is a block diagram schematically showing an optical communication system 1800 according to an example embodiment. The optical communication system 1800 may correspond to one of electronic devices to which the infrared detector illustrated in FIGS. 1 to 12 or the combination of the infrared detector and the optical waveguide illustrated in FIGS. 13 to 17 may be applied.

Referring to FIG. 18, the optical communication system 1800 may include a transmitter 182, a receiver 186, and an optical transmission medium 190 that optically connects the transmitter 182 and the receiver 186. The transmitter 182 may convert an electrical signal into an optical signal and transmit the optical signal to the optical transmission medium 190. In one example, the electrical signal may include data to be transmitted to the receiver 186 through the optical transmission medium 190. In one example, the electrical signal may be generated in the transmitter 182 itself, or may be transmitted to the transmitter 182 from outside the transmitter 182. In one example, the transmitter 182 may include an element capable of electro-optical conversion, and may also include a driver for driving such an element, but is not limited thereto. In one example, the transmitter 182 may include a computer connected to the optical transmission medium 190 by wire. Such a computer may include a light source unit configured to generate an optical signal modulated in response to the electrical signal. In one example, the computer may include a port that may be directly optically connected to the optical transmission medium 190. In one example, an optical signal generation module (or a module directly connected to the optical transmission medium 190) may be provided between the computer and the optical transmission medium 190. An electrical signal including data may be generated in the computer and transmitted to the optical signal generation module, and the optical signal generation module may transmit an optical signal corresponding to the transmitted electrical signal to the optical transmission medium 190.

In one example, the optical transmission medium 190 may be optically connected to a transmitting side and a receiving side in optical communication, and in the case of long-distance communication, may include an optical fiber, and in the case of short-distance communication (e.g., the transmitting side and the receiving side are included in the same device or system), the optical transmission medium 190 may include, but is not limited to, an optical waveguide. In one example, the optical waveguide may include, but is not limited to, a silicon waveguide. The optical waveguide may also be expressed as an optical wave path.

In one example, the receiver 186 may include a component for receiving an electrical signal (data) transmitted from the transmitter 182. An electrical signal generated in the transmitter 182 may be converted into an optical signal and then transmitted to the receiver 186 through the optical transmission medium 190, and thus, the receiver 186 may include a photodetector for detecting the optical signal transmitted from the optical transmission medium 190 and converting the optical signal to an electrical signal. In one example, the photodetector may be a photoelectric conversion device. In one example, the photodetector may include one of the infrared detectors 100, 200, 300, 400, 500, 600, 700, 800, 900, 1000, 1100, 1200 illustrated in FIGS. 1 to 12. In one example, the transmitter 182 may include an optical waveguide optically coupled to the optical transmission medium 190, and the photodetector may be provided to be optically coupled to the optical waveguide. In other words, the optical transmission medium 190 and the photodetector may be optically connected to each other via an optical waveguide. The coupling method described with reference to FIGS. 13 to 17 may be applied to the optical coupling between the photodetector and the optical waveguide but is not limited thereto.

In one example, the receiver 186 may include a processor or module for processing the electrical signal generated by the photodetector through photoelectric conversion.

In one example, the receiver 186 may include a second computer including a photodetector and a processor or module.

In one example, the receiver 186 may include an optical signal receiving module (or a module directly connected to the optical transmission medium 190) directly optically connected to the optical transmission medium 190. In this case, the photodetector may be included in the optical signal receiving module, and the second computer may include a processor or module for processing an electrical signal generated by the photodetector and may be connected to the optical signal receiving module.

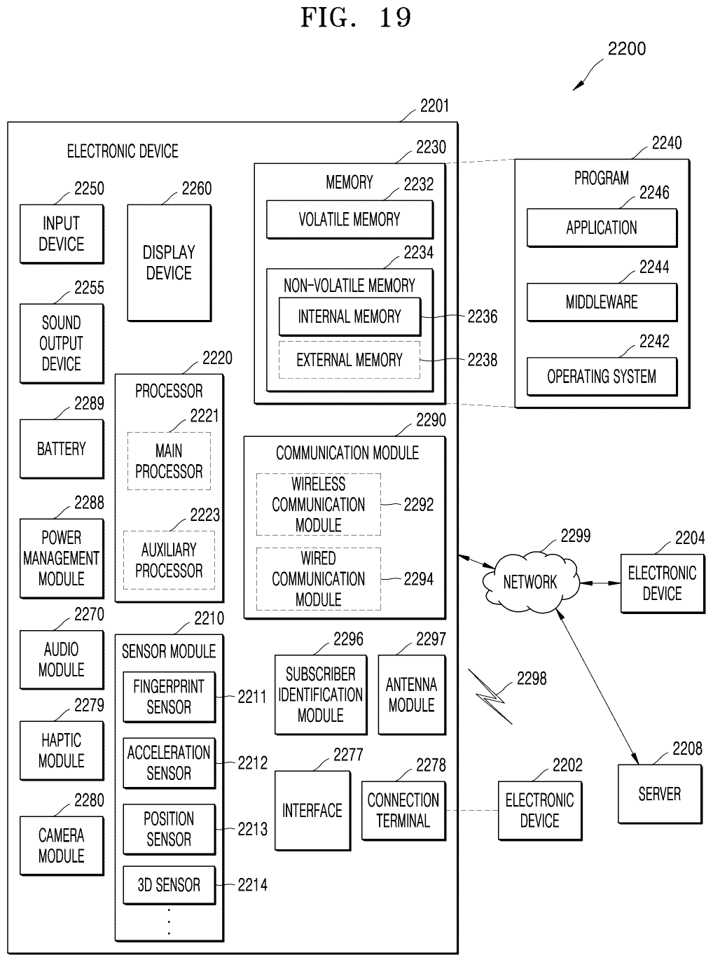

FIG. 19 is a diagram showing a schematic configuration of an electronic device according to an embodiment.

Referring to FIG. 19, in a network environment 2200, an electronic device 2201 may communicate with other electronic device 2202 through a first network 2298 (e.g., short-range wireless communication network, etc.), or may communicate with another electronic device 2204 and/or a server 2208 through a second network 2299 (e.g., a long-distance wireless communication network, etc.). The electronic device 2201 may communicate with the electronic device 2204 through the server 2208. The electronic device 2201 may include a processor 2220, a memory 2230, an input device 2250, an audio output device 2255, a display device 2260, an audio module 2270, a sensor module 2210, an interface 2277, a haptic module 2279, a camera module 2280, a power management module 2288, a battery 2289, a communication module 2290, a subscriber identification module 2296, and/or an antenna module 2297.

In the electronic device 2201, some of these components (e.g., the display device 2260) may be omitted or other components may be added. Some of these components may be implemented as one integrated circuit. For example, a fingerprint sensor 2211 of the sensor module 2210, an iris sensor, an illuminance sensor, etc. may be implemented in a form embedded in the display device 2260 (e.g., a display, etc.).

The processor 2220 may execute software (e.g., a program 2240) to control one or a plurality of other components (e.g., hardware, software components, etc.) of the electronic device 2201 connected to the processor 2220, and may perform various data processing or operations. As part of data processing or operations, the processor 2220 may load commands and/or data received from other components (e.g., the sensor module 2210, the communication module 2290, etc.) into a volatile memory 2232, and may process commands and/or data stored in the volatile memory 2232, and store resulting data in a non-volatile memory 2234. The processor 2220 may include a main processor 2221 (e.g., a central processing unit, an application processor, etc.) and an auxiliary processor 2223 (e.g., a graphics processing unit, an image signal processor, a sensor hub processor, a communication processor, etc.) that may be operated independently or together with the main processor 2221. The auxiliary processor 2223 may use less power than the main processor 2221 and may perform a specialized function.

The auxiliary processor 2223 may control functions and/or states related to some of the components (e.g., the display device 2260, the sensor module 2210, the communication module 2290) of the electronic device 2201 instead of the main processor 2221 while the main processor 2221 is in an inactive state (e.g., sleep state), or together with the main processor 2221 while the main processor 2221 is in an active state (e.g., application execution state). The auxiliary processor 2223 (e.g., an image signal processor, a communication processor, etc.) may be implemented as a part of other functionally related components (e.g., the camera module 2280, the communication module 2290, etc.).

The memory 2230 may store various data required by components of the electronic device 2201 (e.g., the processor 2220, the sensor module 2276, etc.). The data may include, for example, input data and/or output data for software (e.g., the program 2240) and instructions related to the command. The memory 2230 may include a volatile memory 2232 and/or a non-volatile memory 2234. The non-volatile memory 2234 may include an internal memory 2236 and an external memory 2238. The program 2240 may be stored as software in the memory 2230, and may include an operating system 2242, middleware 2244, and/or an application 2246.

The input device 2250 may receive commands and/or data to be used in a component (e.g., the processor 2220) of the electronic device 2201 from the outside of the electronic device 2201 (e.g., a user). The input device 2250 may include a microphone, a mouse, a keyboard, and/or a digital pen (e.g., a stylus pen).

The sound output device 2255 may output a sound signal to the outside of the electronic device 2201. The sound output device 2255 may include a speaker and/or a receiver. The speaker may be used for general purposes, such as multimedia playback or recording playback, and the receiver may be used to receive incoming calls. The receiver may be integrated as a part of the speaker or may be implemented as an independent separate device.

The display device 2260 may visually provide information to the outside of the electronic device 2201. The display device 2260 may include a control circuit for controlling a display, a hologram device, or a projector and a corresponding device. The display device 2260 may include a touch circuitry configured to sense a touch, and/or a sensor circuitry configured to measure the intensity of force generated by the touch (e.g., a pressure sensor, etc.).

The audio module 2270 may convert a sound into an electric signal or, conversely, convert an electric signal into a sound. The audio module 2270 may obtain a sound through the input device 2250 or may output a sound through a speaker and/or headphone of the sound output device 2255 and/or another electronic device (e.g., the electronic device 2202) directly or wirelessly connected to electronic device 2201.

The sensor module 2210 may detect an operating state (e.g., power, temperature, etc.) of the electronic device 2201 or an external environmental state (e.g., user state, etc.), and may generate an electrical signal and/or data value corresponding to the sensed state. The sensor module 2210 may include a fingerprint sensor 2211, an acceleration sensor 2212, a position sensor 2213, a 3D sensor 2214, and the like, and in addition to the above sensors, may include an iris sensor, a gyro sensor, a barometric pressure sensor, a magnetic sensor, a grip sensor, a proximity sensor, a color sensor, an infrared (IR) sensor, a biometric sensor, a temperature sensor, a humidity sensor, and/or an illuminance sensor. In an example, the IR sensor may include one of the infrared detectors 100, 200, 300, 400, 500, 600, 700, 800, 900, 1000, 1100, and 1200 illustrated in FIGS. 1 to 12.

The 3D sensor 2214 may sense a shape and movement of an object by emitting or radiating certain light to the object and analyzing light reflected from the object, and may include a meta-optical device.

The interface 2277 may support one or more designated protocols that may be used by the electronic device 2201 to connect directly or wirelessly with another electronic device (e.g., the electronic device 2102). The interface 2277 may include a High Definition Multimedia Interface (HDMI), a Universal Serial Bus (USB) interface, an SD card interface, and/or an audio interface.

The connection terminal 2278 may include a connector through which the electronic device 2201 may be physically connected to another electronic device (e.g., the electronic device 2202). The connection terminal 2278 may include an HDMI connector, a USB connector, an SD card connector, and/or an audio connector (e.g., a headphone connector).

The haptic module 2279 may convert an electrical signal into a mechanical stimulus (e.g., vibration, movement, etc.) or an electrical stimulus that the user may perceive through tactile or kinesthetic sense. The haptic module 2279 may include a motor, a piezoelectric element, and/or an electrical stimulation device.

The camera module 2280 may capture still images and moving images. The camera module 2280 may include a lens assembly including one or more lenses, image sensors, image signal processors, and/or flashes. The lens assembly included in the camera module 2280 may collect light emitted from an object, which is an imaging target. In an example, the camera module 2280 may be configured to capture at least one of a visible light image and an infrared image of the object. In an example, the image signal processor included in the camera module 2280 may undertake a function for converting the captured infrared image into a visible light image and overlapping the captured infrared image on the visible light image. In an example, the camera module 2280 may include an infrared camera for recognizing an object or obtaining information about the object, and the infrared camera may include one of the infrared detectors 100, 200, 300, 400, 500, 600, 700, 800, 900, 1000, 1100, and 1200 according to the embodiments described above.

The power management module 2288 may manage power supplied to the electronic device 2201. The power management module 2288 may be implemented as part of a Power Management Integrated Circuit (PMIC).

The battery 2289 may supply power to components of the electronic device 2201. The battery 2289 may include a non-rechargeable primary cell, a rechargeable secondary cell, and/or a fuel cell.

The communication module 2290 may establish a direct (e.g., wired) communication channel and/or wireless communication channel between the electronic device 2201 and other electronic devices (e.g., the electronic device 2202, an electronic device 2204, server 2208, etc.) and may support the performance of communication through the established communication channels. The communication module 2290 may include one or more communication processors that operate independently of the processor 2220 (e.g., an application processor) and support direct communication and/or wireless communication. The communication module 2290 may include a wireless communication module 2292 (e.g., a cellular communication module, a short-range wireless communication module, a Global Navigation Satellite System (e.g., GNSS, etc.) communication module) and/or a wired communication module 2294 (e.g., a Local Area Network (LAN) communication module, or a power line communication module, etc.). Among these communication modules, a corresponding communication module may communicate with other electronic devices through the first network 2298 (e.g., a short-range communication network, such as Bluetooth, WiFi Direct, or Infrared Data Association (IrDA)) or the second network 2299 (e.g., a telecommunication network, such as a cellular network, the Internet, or a computer network (LAN and WAN, etc.). The various types of communication modules may be integrated into one component (e.g., a single chip, etc.) or implemented as a plurality of components (e.g., plural chips) separate from each other. In one example, the chip of the communication module may include a chip for optical communication, and may include one of the infrared detectors 100, 200, 300, 400, 500, 600, 700, 800, 900, 1000, 1100, and 1200 but is not limited thereto. The wireless communication module 2292 may identify and authenticate the electronic device 2201 within a communication network, such as the first network 2298 and/or the second network 2299 by using subscriber information (e.g., International Mobile Subscriber Identifier (IMSI)) stored in a subscriber identification module 2296.

The antenna module 2297 may transmit or receive signals and/or power to and from the outside (e.g., other electronic devices, etc.). The antenna may include a radiator having a conductive pattern formed on a substrate (e.g., PCB, etc.). The antenna module 2297 may include one or a plurality of antennas. If a plurality of antennas is included in the antenna module 2297, an antenna suitable for a communication method used in a communication network, such as the first network 2298 and/or the second network 2299 from among the plurality of antennas may be selected by the communication module 2290. Signals and/or power may be transmitted or received between the communication module 2290 and another electronic device through the selected antenna. In addition to the antenna, other components (e.g., an RFIC, etc.) may be included as a part of the antenna module 2297.

Some of the components are connected to each other through a communication method between peripheral devices (e.g., a bus, a General Purpose Input and Output (GPIO), a Serial Peripheral Interface (SPI), a Mobile Industry Processor Interface (MIPI), etc.), and may interchange signals (e.g., commands, data, etc.).

The command or data may be transmitted or received between the electronic device 2201 and the external electronic device 2204 through the server 2208 connected to the second network 2299. The other electronic devices 2202 and 2204 may be the same or different types of electronic device 2201. All or some of operations performed in the electronic device 2201 may be performed in one or more of the other electronic devices 2202, 2204, and 2208. For example, when the electronic device 2201 needs to perform a function or service, the electronic device 2201 may request one or more other electronic devices to perform part or all function or service instead of executing the function or service itself. One or more other electronic devices receiving the request may execute an additional function or service related to the request, and transmit a result of the execution to the electronic device 2201. For this purpose, cloud computing, distributed computing, and/or client-server computing technologies may be used.

The disclosed infrared detector is a Ge-based phototransistor type, has a low driving voltage of 3V or less, is capable of high-speed operation of 5 GHz or more (e.g., 10 GHz or more), and may have a gain of 10 or more (e.g., 100 or more). Accordingly, if the disclosed infrared detector is used as a light receiving element, light detection sensitivity may be increased, and thus an output of a light source that emits light towards a light receiving element may be lowered. In other words, in the case of an electronic device (e.g., optical communication system) including the disclosed infrared detector, power consumption by the light source may be reduced.

While many matters have been described in detail in the above description, they should be construed as illustrative of embodiments rather than to limit the scope of the disclosure. Therefore, the scope of the disclosure should not be defined by the embodiments described above but should be determined by the technical spirit described in the claims.

It should be understood that example embodiments described herein should be considered in a descriptive sense only and not for purposes of limitation. Descriptions of features or aspects within each embodiment should typically be considered as available for other similar features or aspects in other embodiments. While one or more example embodiments have been described with reference to the figures, it will be understood by those of ordinary skill in the art that various changes in form and details may be made therein without departing from the spirit and scope as defined by the following claims and their equivalents.

What is claimed is:

1. An infrared detector comprising:
a substrate;
a germanium (Ge)-based infrared absorption layer provided on the substrate;
a first electrode layer provided on the infrared absorption layer;
a second electrode layer provided on the infrared absorption layer and spaced apart from the first electrode layer in a first direction; and
a first gate electrode layer provided between the first electrode layer and the second electrode layer in the first direction, the first gate electrode layer facing the infrared absorption layer and spaced apart from the infrared absorption layer in a second direction crossing the first direction.

2. The infrared detector of claim 1, wherein the infrared absorption layer extends on or below the first electrode layer and the second electrode layer, and the first electrode layer and the second electrode layer directly contact the infrared absorption layer.

3. The infrared detector of claim 1, wherein the infrared absorption layer extends on or below the first electrode layer and the second electrode layer,
wherein the infrared absorption layer includes:
a first doped layer provided at a position corresponding to the first electrode layer; and
a second doped layer provided at a position corresponding to the second electrode layer and spaced apart from the first doped layer, and
wherein the first electrode layer is in direct contact with the first doped layer, and the second electrode layer is in direct contact with the second doped layer.

4. The infrared detector of claim 3, wherein each of the first doped layer and the second doped layer includes one of an n-type dopant and a p-type dopant.

5. The infrared detector of claim 1, wherein each of the first doped layer and the second doped layer has a doping concentration gradient in a direction away from the first gate electrode layer.

6. The infrared detector of claim 1, wherein the first gate electrode layer is disposed above or below the infrared absorption layer.

7. The infrared detector of claim 1, further comprising a second gate electrode layer, the second gate electrode facing the first gate electrode layer with the infrared absorption layer therebetween and being spaced apart from the infrared absorption layer.

8. The infrared detector of claim 1, further comprising a first interlayer material layer between the substrate and the infrared absorption layer,
wherein the first interlayer material layer includes a silicon (Si) layer.

9. The infrared detector of claim 1, further comprising a second interlayer material layer on the substrate,
wherein the second interlayer material layer includes a groove, and
the infrared absorption layer is provided in the groove.

10. The infrared detector of claim 9, wherein the second interlayer material layer includes:
a third doped layer at a position corresponding to the first electrode layer; and
a fourth doped layer at a position corresponding to the second electrode layer, and
wherein the groove is located between the third doped layer and the fourth doped layer in the first direction, the first electrode layer is in direct contact with the third doped layer, and the second electrode layer is in direct contact with the fourth doped layer.

11. The infrared detector of claim 10, wherein the third doped layer and the fourth doped layer are spaced apart from the infrared absorption layer.

12. The infrared detector of claim 10, wherein the third doped layer and the fourth doped layer extend toward a lower surface of the second interlayer material layer.

13. The infrared detector of claim 10, wherein each of the third doped layer and the fourth doped layer has a doping concentration gradient in a direction away from the first gate electrode layer.

14. The infrared detector of claim 10, wherein each of the third doped layer and the fourth doped layer includes one of an n-type dopant and a p-type dopant.

15. The infrared detector of claim 9, wherein the first gate electrode layer is disposed above or below the infrared absorption layer.

16. The infrared detector of claim 9, further comprising a second gate electrode layer, the second gate electrode layer facing the first gate electrode layer with the infrared absorption layer therebetween and being spaced apart from the infrared absorption layer.

17. The infrared detector of claim 1, wherein the infrared absorption layer includes a plurality of infrared absorption layers, the plurality of infrared absorption layers being stacked in a direction perpendicular to the substrate and spaced apart from each other.

18. The infrared detector of claim 1, wherein the substrate includes:
a base substrate; and
an interlayer insulating layer on the base substrate.

19. The infrared detector of claim 1, wherein the substrate is a single layer, the substrate includes a silicon layer or a silicon oxide layer, and the substrate is in direct contact with the infrared absorption layer.

20. An electronic device comprising:
an infrared detector; and
a waveguide connected to the infrared detector,
wherein the infrared detector includes:
a substrate;
a germanium (Ge)-based infrared absorption layer provided on the substrate;
a first electrode layer provided on the infrared absorption layer;
a second electrode layer provided on the infrared absorption layer and spaced apart from the first electrode layer in a first direction; and
a first gate electrode layer provided between the first electrode layer and the second electrode layer in the first direction, the first gate electrode layer facing the infrared absorption layer and spaced apart from the infrared absorption layer in a second direction crossing the first direction, and
wherein the infrared detector and the waveguide are connected to each other by a butt coupling method, an evanescent coupling method, or a diffraction grating coupling method.
